(19) United States
(12) Patent Application Publication
(10) Pub. No.: US 2010/0307561 A1
(43) Pub. Date: Dec. 9, 2010

(54) DOPED METAL CONTACT

(75) Inventors: Benyamin Buller, Sylvania, OH (US); Long Cheng, Perrysburg, OH (US); Akhlesh Gupta, Sylvania, OH (US); Anke Abken, Whitehouse, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/793,461

(22) Filed: Jun. 3, 2010

Related U.S. Application Data
(60) Provisional application No. 61/184,219, filed on Jun. 4, 2009.

(51) Int. Cl. H01L 31/042; H01L 31/0256; H01L 31/0288; H01L 31/18

(52) U.S. Cl. 136/244; 136/262; 136/255; 438/86; 257/E31.032; 257/E31.003

(57) ABSTRACT

A photovoltaic device can include a second metal layer adjacent to a first layer, where the first layer is positioned adjacent to a substrate, and where the second metal layer includes a dopant; and a copper-indium-gallium diselenide (CIGS) layer adjacent to the second metal layer.

### CLAIM FOR PRIORITY

This application claims priority under 35 U.S.C. §119(e) to U.S. Provisional Patent Application Ser. No. 61/184,219 filed on Jun. 4, 2009, which is hereby incorporated by reference.

### TECHNICAL FIELD

The present invention relates to doped metal contact, particularly for use in photovoltaic devices.

### BACKGROUND

Photovoltaic devices can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic devices can also contain one or more transparent conductive oxide layers, which are also often conductors of electrical charge.

### DESCRIPTION OF DRAWINGS

FIG. 1 is a schematic of a photovoltaic device having multiple layers.

FIG. 2 is a schematic of a photovoltaic device having multiple layers.

FIG. 3 is a schematic of a photovoltaic device having multiple layers.

### DETAILED DESCRIPTION

Photovoltaic devices can include multiple layers created on a substrate (or superstrate). For example, a photovoltaic device can include a barrier layer, a transparent conductive oxide (TCO) layer, a buffer layer, and a semiconductor layer formed in a stack on a substrate. Each layer may in turn include more than one layer or film. For example, the semiconductor layer can include a first film including a semiconductor window layer, such as a cadmium sulfide layer, formed on the buffer layer and a second film including a semiconductor absorber layer, such as a cadmium telluride layer formed on the semiconductor window layer. Additionally, each layer can cover all or a portion of the device and/or all or a portion of the layer or substrate underlying the layer. For example, a “layer” can include any amount of any material that contacts all or a portion of a surface.

Thin-film photovoltaics, such as copper-indium-gallium-diselenide (CIGS), have proven effective as low-cost alternatives to more expensive silicon semiconductors. The CIGS structure can be deposited adjacent to a back contact for the photovoltaic device. The CIGS structure can be deposited adjacent to a barrier layer which in turn is adjacent to the back contact. The back contact can include any suitable material, including one or more metals. A variety of materials are available for the back contact metal, including, for example, molybdenum, aluminum, chromium, iron, nickel, titanium, vanadium, manganese, cobalt, zinc, ruthenium, tungsten, silver, gold, or platinum, which can be mixtures or alloys thereof. Molybdenum functions particularly well as a back contact metal due to its relative stability at processing temperatures and low contact resistance. Chromium also exhibits desired electrical properties. The back contact can include multiple layers. For example, the back contact can include a first layer adjacent to a substrate and a metal second layer adjacent to the barrier first layer. The first layer can be a sodium barrier layer. After depositing a CIGS layer onto the back contact, a semiconductor window layer, such as a zinc oxide, can be deposited to form the p-n junction. A transparent conductive oxide layer can be deposited on glass, for example a soda-lime glass, and contacted with the window layer to serve as a front contact for the device.

In one aspect, a photovoltaic device can include a second metal layer adjacent to a first layer, where the first layer is positioned adjacent to a substrate, and where the second metal layer includes a dopant; and a copper-indium-gallium diselenide (CIGS) layer adjacent to the second metal layer.

The first layer can include a metal or a sodium barrier material. The first layer can include a metal, for example, chromium, or a dielectric material, for example an oxide or nitride which can include titanium, silicon, aluminum, or zirconium. The second metal layer can include molybdenum. The dopant can include sodium. The first layer can include a chromium layer, and the second metal layer can include a sodium-doped molybdenum layer. The photovoltaic device can include a cadmium sulfide buffer layer adjacent to the CIGS layer; an intrinsic zinc oxide layer adjacent to the cadmium sulfide buffer layer; and a doped zinc oxide layer adjacent to the intrinsic zinc oxide layer. The doped zinc oxide can include an aluminum oxide dopant. The photovoltaic device can include a transparent conductive oxide layer adjacent to the doped zinc oxide layer. The photovoltaic device can include one or more layers adjacent to the transparent conductive oxide layer. The photovoltaic device can include a front support adjacent to the transparent conductive oxide layer. The front support can include a glass, for example a soda-lime glass. In certain circumstances, the substrate can include a glass, for example a soda-lime glass.

In one aspect, a method for manufacturing a photovoltaic device can include depositing a first layer adjacent to a substrate; depositing a second metal layer adjacent to the first layer, where the second metal layer includes a dopant; and depositing a copper-indium-gallium diselenide (CIGS) layer adjacent to the second metal layer.

The first layer can include a metal or a dielectric material. The first layer can include a chromium layer. The second metal layer can include molybdenum. The dopant can include sodium. The first layer can include a chromium layer. The second metal layer can include a sodium-doped molybdenum layer. The method can include depositing a cadmium sulfide buffer layer adjacent to the CIGS layer; depositing an intrinsic zinc oxide layer adjacent to the cadmium sulfide buffer layer; and depositing a doped zinc oxide layer adjacent to the intrinsic zinc oxide layer. The method can include doping the zinc oxide layer with an aluminum oxide. The method can include depositing a transparent conductive layer adjacent to the doped zinc oxide layer. The method can include doping a zinc oxide layer with an aluminum oxide. Depositing a CIGS layer can include transporting a vapor. Depositing a chromium layer can include sputtering. Depositing a second metal layer can include sputtering a sodium-doped molybdenum. Depositing an intrinsic zinc oxide layer can include sputtering. Depositing a doped zinc oxide layer can include sputtering. The method can include heating the substrate, chromium layer, and sodium-doped molybdenum, prior to depositing a CIGS layer. Depositing a CIGS layer can include first evaporating a copper, then sputtering gallium, and then co-evaporating indium and selenium. Depositing a CIGS layer can include co-evaporating a copper, a gallium, an indium, and a selenium. Depositing a CIGS layer can include depositing copper, gallium, and indium in the presence of selenium flux. Depositing a CIGS layer can include depositing indium in the presence of selenium flux. Depositing a CIGS layer can include depositing copper; depositing gallium on the copper; depositing indium on the gallium; depositing selenium on the indium; and heating the copper, gallium, indium, and selenium. The method can include depositing one or more layers adjacent to the transparent conductive oxide layer. The method can include depositing a front support adjacent to the transparent conductive oxide layer. The front support can include a glass, for example a soda-lime glass. In certain circumstances, the substrate can include a glass, for example a soda-lime glass.

In one aspect, a photovoltaic module may include a plurality of photovoltaic cells adjacent to a substrate. The photovoltaic module may include a back cover adjacent to the plurality of photovoltaic cells. The plurality of photovoltaic cells may include a second metal layer adjacent to a first layer. The first layer may be positioned adjacent to a substrate. The second metal layer may include a dopant. The plurality of photovoltaic cells may include a copper-indium-gallium diselenide (CIGS) layer adjacent to the second metal layer.

The photovoltaic module may include a first strip of tape having a length distributed along a contact region of each photovoltaic cell. The first strip of tape may include a front surface and a back surface. Each surface may contain an adhesive. The photovoltaic module may include a first lead foil distributed along the length of the first strip of tape. The photovoltaic module may include a second strip of tape, having a length shorter than that of the first strip of tape, distributed along the length and between the ends of the first strip of tape. The second strip of tape may include a front and back surface. Each surface may contain an adhesive. The photovoltaic module may include a second lead foil, having a length shorter than that of the second strip of tape, distributed along the length of the second strip of tape. The photovoltaic module may include a plurality of parallel bus bars, positioned adjacent and perpendicular to the first and second strips of tape. Each one of the plurality of parallel bus bars may contact one of the first or second lead foils. The photovoltaic module may include first and second submodules. The first submodule may include two or more cells of the plurality of photovoltaic cells connected in series. The second submodule may include another two or more cells of the plurality of photovoltaic cells connected in series. The first and second submodules may be connected in parallel through a shared cell.

In one aspect, a method for generating electricity may include illuminating a photovoltaic cell with a beam of light to generate a photocurrent. The method may include collecting the generated photocurrent. The photovoltaic cell may include a second metal layer adjacent to a first layer. The first layer may be positioned adjacent to a substrate. The second metal layer may include a dopant. Each one of the photovoltaic cells may include a copper-indium-gallium diselenide (CIGS) layer adjacent to the second metal layer.

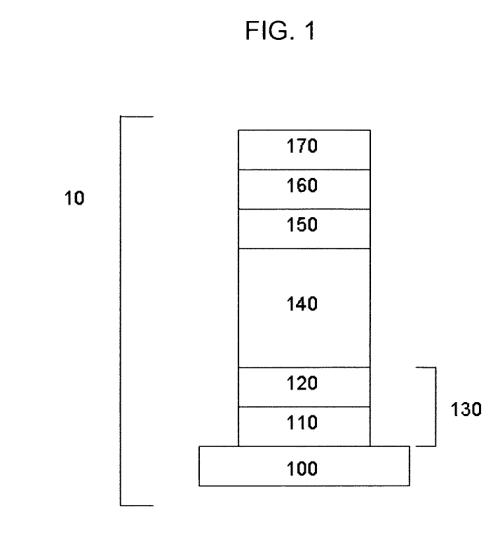

Referring to FIG. 1 by way of example, a photovoltaic device 10 can include a first layer 110 deposited on a soda-lime glass substrate 100. First layer 110 can include a sodium barrier material. First layer 110 can include a metal or a non-metal, or any suitable combination of metal and non-metal materials. For example, first layer 110 can include chromium or any other suitable metal. First layer 110 can include a non-metal material such as a dielectric material. For example, first layer 110 can include oxides and nitrides of titanium, silicon, aluminum, or zirconium, or any other suitable material. For example, first layer 110 can include SiO₂. First layer 110 can be deposited using any suitable means, including sputtering.

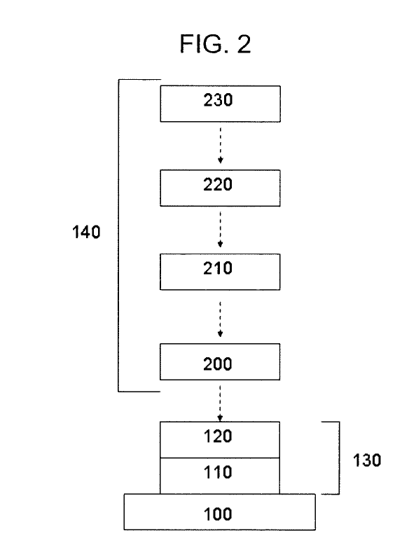

A second layer 120 can be formed on first layer 110. Second layer 120 can include metal. Second metal layer 120 can include molybdenum and can be doped with sodium to form sodium-doped molybdenum layer 120. Sodium-doped molybdenum layer 120 can be deposited onto first layer 110 using any suitable means, including sputtering. Sodium-doped molybdenum layer 120 and first layer 110 can form back contact metal 130. A copper-indium-gallium-diselenide layer (CIGS) 140 can be deposited onto contact metal 130. Referring to FIG. 2, CIGS layer 140 may include copper layer 200, gallium layer 210, indium layer 220, and selenium layer 230. CIGS layer 140 can be formed and deposited using any suitable method. For example, substrate 100 and back contact metal 130 can be heated to a deposition temperature above about 200° C. A copper can be evaporated over the substrate layers; a gallium can be sputtered onto the copper; and then an indium and a selenium can be co-evaporated over the gallium. Alternatively, the copper, gallium, indium, and selenium can be co-evaporated over the substrate. In one variation, the copper, gallium, and indium all go through a selenization process. For example, the copper, gallium, and indium can be deposited and then heated in the presence of a selenium flux. Alternatively, the copper, gallium, and indium can be deposited in the presence of a hydrogen selenide gas. Photovoltaic device 10 can undergo heat treatment during which sodium from sodium-doped molybdenum layer 120 can diffuse into first layer 110 to create a concentration gradient. It should be noted that the metal contact layer(s) are not limited to any specific metals. First layer 110 and second metal layer 120 can include any suitable metal or alloy, including molybdenum, aluminum, chromium, iron, nickel, titanium, vanadium, manganese, cobalt, zinc, ruthenium, tungsten, silver, gold, or platinum. First layer 110 and second metal layer 120 can also be of a suitable thickness, for example greater than about 10 A, greater than about 20 A, greater than about 50 A, greater than about 100 A, greater than about 250 A, greater than about 500 A, less than about 2000 A, less than about 1500 A, less than about 1000 A, or less than about 750 A. One of the layers can include a suitable dopant material, including copper, antimony, potassium, sodium, cesium, silver, gold, phosphorous, arsenic, or bismuth. Each layer can be substantially pure, containing a single metal or a binary alloy, mixture, or solid solution thereof.

Continuing, a cadmium sulfide buffer layer 150 can be deposited adjacent to CIGS layer 140. Cadmium sulfide buffer layer 150 can have a thickness of about 500 A. Cadmium sulfide buffer layer 150 can be deposited using any known deposition technique, including vapor transport. A layer of intrinsic zinc oxide 160 can be deposited onto buffer layer 150. Intrinsic zinc oxide layer 160 can have a thickness of about 600 A. Intrinsic zinc oxide layer 160 can be deposited using any suitable method, including sputtering. Intrinsic zinc oxide layer 160 can also be deposited in the presence of a gas, for example argon gas, oxygen gas, or a combination thereof. A doped zinc oxide 170 can be deposited onto intrinsic zinc oxide 160. Doped zinc oxide 170 can have a thickness of about 5000 A. Doped zinc oxide 170 can be deposited using any suitable deposition method, including sputtering. Doped zinc oxide 170 can be deposited in the presence of a gas, for example argon gas.

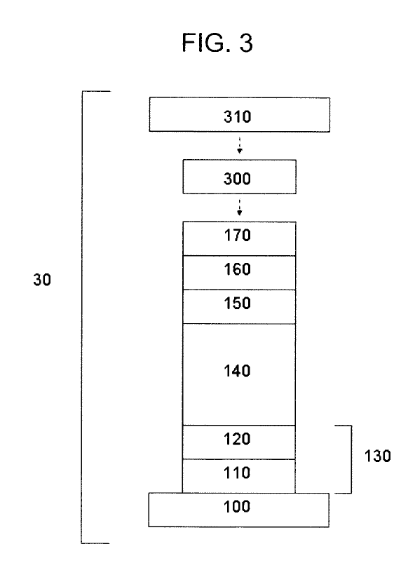

Referring to FIG. 3, photovoltaic device 30 can include a transparent conductive oxide layer 300 deposited adjacent to doped zinc oxide 170 to serve as a front contact. Transparent conductive oxide layer 300 can include any suitable material, for example cadmium stannate. One or more additional layer(s) can be deposited adjacent to transparent conductive oxide layer 300, including for example one or more barrier layers to block the diffusion of unwanted chemicals. The one or more barrier layers can include any suitable material, including a silicon nitride, silicon oxide, aluminum-doped silicon oxide, boron-doped silicon nitride, phosphorus-doped silicon nitride, silicon oxide-nitride, or any combination or alloy thereof. A front support 310 can be deposited adjacent to transparent conductive oxide layer 300. Front support 310 can include any suitable material, including glass, for example soda-lime glass.

A variety of deposition techniques are available for depositing the layers discussed above, including for example, low pressure chemical vapor deposition, atmospheric pressure chemical vapor deposition, plasma-enhanced chemical vapor deposition, thermal chemical vapor deposition, DC or AC sputtering, spin-on deposition, and spray-pyrolysis.

A sputtering target can be manufactured by ingot metallurgy. A sputtering target can be manufactured from cadmium, tin, silicon, or aluminum, or combinations or alloys thereof suitable to make the layer. For example, the target can be Si₈₅Al₁₅. The cadmium and tin can be present in the same target in stoichiometrically proper amounts. A sputtering target can be manufactured as a single piece in any suitable shape. A sputtering target can be a tube. A sputtering target can be manufactured by casting a metallic material into any suitable shape, such as a tube.

A sputtering target can be manufactured from more than one piece. A sputtering target can be manufactured from more than one piece of metal, for example, a piece of cadmium and a piece of tin. The cadmium and tin can be manufactured in any suitable shape, such as sleeves, and can be joined or connected in any suitable manner or configuration. For example, a piece of cadmium and a piece of tin can be welded together to form the sputtering target. One sleeve can be positioned within another sleeve.

A sputtering target can be manufactured by powder metallurgy. A sputtering target can be formed by consolidating metallic powder (e.g., cadmium or tin powder) to form the target. The metallic powder can be consolidated in any suitable process (e.g., pressing such as isostatic pressing) and in any suitable shape. The consolidating can occur at any suitable temperature. A sputtering target can be formed from metallic powder including more than one metal powder (e.g., cadmium and tin). More than one metallic powder can be present in stoichiometrically proper amounts.

A sputter target can be manufactured by positioning wire including target material adjacent to a base. For example wire including target material can be wrapped around a base tube. The wire can include multiple metals (e.g., cadmium and tin) present in stoichiometrically proper amounts. The base tube can be formed from a material that will not be sputtered. The wire can be pressed (e.g., by isostatic pressing).

A sputter target can be manufactured by spraying a target material onto a base. Metallic target material can be sprayed by any suitable spraying process, including thermal spraying and plasma spraying. The metallic target material can include multiple metals (e.g., cadmium and tin), present in stoichiometrically proper amounts. The base onto which the metallic target material is sprayed can be a tube.

Photovoltaic devices/cells fabricated using the methods discussed herein may be incorporated into one or more photovoltaic modules, each of which may include one or more submodules. Such modules may by incorporated into various systems for generating electricity. For example, a photovoltaic module may include one or more submodules consisting of multiple photovoltaic cells connected in series. One or more submodules may be connected in parallel via a shared cell to form a photovoltaic module.

A bus bar assembly may be attached to a contact surface of a photovoltaic module to enable connection to additional electrical components (e.g., one or more additional modules). For example, a first strip of double-sided tape may be distributed along a length of the module, and a first lead foil may be applied adjacent thereto. A second strip of double-sided tape (smaller than the first strip) may be applied adjacent to the first lead foil. A second lead foil may be applied adjacent to the second strip of double-sided tape. The tape and lead foils may be positioned such that at least one portion of the first lead foil is exposed, and at least one portion of the second lead foil is exposed. Following application of the tape and lead foils, a plurality of bus bars may be positioned along the contact region of the module. The bus bars may be positioned parallel from one another, at any suitable distance apart. For example, the plurality of bus bars may include at least one bus bar positioned on a portion of the first lead foil, and at least one bus bar positioned on a portion of the second lead foil. The bus bar, along with the portion of lead foil on which it has been applied, may define a positive or negative region. A roller may be used to create a loop in a section of the first or second lead foil. The loop may be threaded through the hole of a subsequently deposited back glass. The photovoltaic module may be connected to other electronic components, including, for example, one or more additional photovoltaic modules. For example, the photovoltaic module may be electrically connected to one or more additional photovoltaic modules to form a photovoltaic array.

The photovoltaic cells/modules/arrays may be included in a system for generating electricity. For example, a photovoltaic cell may be illuminated with a beam of light to generate a photocurrent. The photocurrent may be collected and converted from direct current (DC) to alternating current (AC) and distributed to a power grid. Light of any suitable wavelength may be directed at the cell to produce the photocurrent, including, for example, more than 400 nm, or less than 700 nm (e.g., ultraviolet light). Photocurrent generated from one photovoltaic cell may be combined with photocurrent generated from other photovoltaic cells. For example, the photovoltaic cells may be part of one or more photovoltaic modules in a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A photovoltaic device, comprising:
a second metal layer adjacent to a first layer, wherein the first layer is positioned adjacent to a substrate, and wherein the second metal layer includes a dopant; and
a copper-indium-gallium diselenide (CIGS) layer adjacent to the second metal layer.

2. The photovoltaic device of claim 1, wherein the first layer comprises a metal.

3. The photovoltaic device of claim 2, wherein the first layer comprises chromium.

4. The photovoltaic device of claim 1, wherein the first layer comprises a comprises a sodium barrier material.

5. The photovoltaic device of claim 4, wherein the first layer comprises a dielectric material.

6. The photovoltaic device of claim 4, wherein the first layer comprises an oxide or a nitride.

7. The photovoltaic device of claim 4, wherein the first layer comprises a material selected from the group consisting of titanium, silicon, aluminum, and zirconium.

8. The photovoltaic device of claim 1, wherein the second metal layer comprises a molybdenum.

9. The photovoltaic device of claim 1, wherein the dopant comprises a sodium.

10. The photovoltaic device of claim 1, wherein the first layer comprises a chromium layer, and the second metal layer comprises a sodium-doped molybdenum layer.

11. The photovoltaic device of claim 10, further comprising:
a cadmium sulfide buffer layer adjacent to the CIGS layer;
an intrinsic zinc oxide layer adjacent to the cadmium sulfide buffer layer; and
a doped zinc oxide layer adjacent to the intrinsic zinc oxide layer.

12. The photovoltaic device of claim 11, wherein the doped zinc oxide comprises an aluminum oxide dopant.

13. The photovoltaic device of claim 11, further comprising:
a transparent conductive oxide layer adjacent to the doped zinc oxide layer; and
one or more layers adjacent to the transparent conductive oxide layer.

14. A method for manufacturing a photovoltaic device, the method comprising:
depositing a first layer adjacent to a substrate;
depositing a second metal layer adjacent to the first layer, wherein the second metal layer includes a dopant; and
depositing a copper-indium-gallium diselenide (CIGS) layer adjacent to the second metal layer.

15. The method of claim 14, further comprising:
depositing a cadmium sulfide buffer layer adjacent to the CIGS layer;
depositing an intrinsic zinc oxide layer adjacent to the cadmium sulfide buffer layer; and
depositing a doped zinc oxide layer adjacent to the intrinsic zinc oxide layer.

16. The method of claim 14, further comprising doping the zinc oxide layer with an aluminum oxide.

17. A photovoltaic module comprising:
a plurality of photovoltaic cells adjacent to a substrate; and
a back cover adjacent to the plurality of photovoltaic cells, the plurality of photovoltaic cells comprising:
a second metal layer adjacent to a first layer, wherein the first layer is positioned adjacent to a substrate, and wherein the second metal layer includes a dopant; and
a copper-indium-gallium diselenide (CIGS) layer adjacent to the second metal layer.

18. The photovoltaic module of claim 17, further comprising:
a first strip of tape having a length distributed along a contact region of each photovoltaic cell, the first strip of tape comprising a front surface and a back surface, each surface containing an adhesive;
a first lead foil distributed along the length of the first strip of tape;
a second strip of tape, having a length shorter than that of the first strip of tape, distributed along the length and between the ends of the first strip of tape, wherein the second strip of tape comprises a front and back surface, each containing an adhesive;
a second lead foil, having a length shorter than that of the second strip of tape, distributed along the length of the second strip of tape; and
a plurality of parallel bus bars, positioned adjacent and perpendicular to the first and second strips of tape, wherein each one of the plurality of parallel bus bars contacts one of the first or second lead foils.

19. The photovoltaic module of claim 18, further comprising first and second submodules, wherein the first submodule comprises two or more cells of the plurality of photovoltaic cells connected in series, and the second submodule comprises another two or more cells of the plurality of photovoltaic cells connected in series, wherein the first and second submodules are connected in parallel through a shared cell.

20. A method for generating electricity, the method comprising:
illuminating a photovoltaic cell with a beam of light to generate a photocurrent; and
collecting the generated photocurrent, wherein the photovoltaic cell comprises:
a second metal layer adjacent to a first layer, wherein the first layer is positioned adjacent to a substrate, and wherein the second metal layer includes a dopant; and
a copper-indium-gallium diselenide (CIGS) layer adjacent to the second metal layer.
